(19) United States
(12) Patent Application Publication
(10) Pub. No.: US 2007/0084507 A1
(43) Pub. Date: Apr. 19, 2007

(54) Dye-sensitized photovoltaic cell and method for producing electrode substrate for the photovoltaic cell

(76) Inventors: Chang Ho Noh, Suwon-si (KR); Jin Young Kim, Suwon-si (KR); Ki Yong Song, Seoul (KR); Sung Hen Cho, Seoul (KR)

Correspondence Address: CANTOR COLBURN, LLP, 55 GRIFFIN ROAD SOUTH, BLOOMFIELD, CT, 06002, US

(21) Appl. No.: 11/385,127

(22) Filed: Mar. 21, 2006

(30) Foreign Application Priority Data
Oct. 19, 2005 (KR) 2005-98546

(51) Int. Cl. H01L 31/00

(52) U.S. Cl. 136/263

(57) ABSTRACT

A dye-sensitized photovoltaic cell including a first electrode, a semiconductor layer formed on the first electrode, a dye formed on a surface of the semiconductor layer, a second electrode arranged opposite to the first electrode and an electrolyte disposed between the first and second electrodes. The second electrode includes a transparent substrate, a photocatalytic layer formed on the transparent substrate, and a metal catalyst layer formed on the photocatalytic layer.

This application claims priority to Korean Patent Application No. 2005-98546_filed on Oct. 19, 2005, and all the benefits accruing therefrom under 35 U.S.C. §119, the contents of which are herein incorporated by reference in its entirety.

### BACKGROUND OF THE INVENTION

1. Field of the Invention

The present invention relates to a dye-sensitized photovoltaic cell comprising a photocatalytic layer and a metal catalyst layer formed on the photocatalytic layer, and a method for producing an electrode substrate for the photovoltaic cell. More particularly, the present invention relates to a photovoltaic cell with high power conversion efficiency in which a metal catalyst layer is uniformly formed over a transparent substrate by simple light exposure and dipping treatments using a photocatalytic layer and a water-soluble polymer layer to produce a second electrode, thus providing economical advantages due to a reduction of fabrication costs and processes, and a method for producing an electrode substrate for the photovoltaic cell.

2. Description of the Related Art

In recent years, numerous studies have focused on various alternative energy sources for conventional fossil fuels to solve urgent energy consumption problems. Particularly, extensive research into effective utilization of natural energy resources, including wind power, atomic energy and solar energy, has been conducted to replace petroleum resources that may be used up within the next several decades. Photovoltaic cells utilize inexhaustible solar energy, unlike other energy sources, and are environmentally friendly. Since the first selenium (Se) photovoltaic cell was developed in 1983, silicon (Si) photovoltaic cells have drawn a great deal of attention and interest.

However, since silicon photovoltaic cells incur considerable fabrication costs, there are some limitations in the practical application and improvement in the efficiency of the silicon photovoltaic cells. To overcome these limitations, the development of dye-sensitized photovoltaic cells that can be fabricated at reduced costs is actively under consideration.

Unlike silicon photovoltaic cells, dye-sensitized photovoltaic cells are photoelectrochemical photovoltaic cells that consist essentially of photosensitive dye molecules capable of absorbing visible rays to form electron-hole pairs and a transition metal oxide for transferring the generated electrons. Various dye-sensitized photovoltaic cells have hitherto been developed. Of these, a representative dye-sensitized photovoltaic cell was reported by Gratzel et al. in Switzerland in 1991. The photovoltaic cell developed by Gratzel et al. comprises a semiconductor electrode composed of titanium dioxide nanoparticles covered with dye molecules, a counter electrode (e.g., a platinum electrode) and an electrolyte filled between the electrodes. Since this photovoltaic cell is fabricated at low costs per electric power generated when compared to conventional silicon cells, it has received a great deal of attention due to the possibility of replacement of conventional photovoltaic cells.

Particularly, considerable attention has focused on dye-sensitized flexible photovoltaic cells using flexible transparent substrates, e.g., plastic substrates, in that such photovoltaic cells can be employed in a wide variety of applications due to their inherent flexibility. However, since the flexibility of dye-sensitized flexible photovoltaic cells enables the formation of metal oxides, such as TiO₂, constituting semiconductor electrodes only at low temperatures (200° C. or below), high reliability of the metal oxides cannot be ensured and thus sufficiently high power conversion efficiency is not achieved.

To overcome these problems, PCT Publication WO 99/066520 discloses a reversed dye-sensitized photovoltaic cell including a first conductive film on which a metal oxide is deposited, a metal oxide semiconductor film, a transparent second conductive film on which a metal, e.g., platinum, is deposited, and an electrolyte filled between the semiconductor film and the second conductive film wherein the first conductive film is formed of a metal foil, e.g., zinc or titanium foil, to enable the deposition of the metal oxide at a high temperature of 400-500° C.

U.S. Patent Publication No. 2003/0192584 discloses a flexible photovoltaic cell including a first substrate, an interconnected nanoparticle material layer deposited on the metal foil, a charge carrier material layer, such as an electrolyte, a catalytic media layer made of platinum, osmium, ruthenium, cobalt, rhodium, nickel or the like, and a second light-transmitting and flexible substrate wherein the first substrate is formed of a metal foil to enable high-temperature processing at 400-500° C.

These conventional photovoltaic cells have advantages in that one of the constituent electrodes is formed of a heat-resistant metal foil to enable high-temperature processing, leading to an improvement in the characteristics of metal oxides. However, since the formation of the metal catalyst layers, such as platinum layers, as second electrodes (i.e. counter electrodes) needs the use of expensive vacuum deposition apparatuses, e.g., sputters, the fabrication of the photovoltaic cells is inefficient and uneconomical in terms of costs and processes. Furthermore, sufficient transparency and transmittance of the second electrodes (i.e. counter electrodes) must be guaranteed to increase the light absorptivity of the conventional photovoltaic cells.

### SUMMARY OF THE INVENTION

An exemplary embodiment according to the present invention provides a dye-sensitized photovoltaic cell including a first electrode, a semiconductor layer formed on the first electrode, a dye formed on a surface of the semiconductor layer, a second electrode arranged opposite to the first electrode and an electrolyte filled into a space formed between the first and second electrodes. The second electrode includes a photocatalytic layer formed sequentially on a transparent substrate and a metal catalyst layer formed on the photocatalytic layer.

Another exemplary embodiment according to the present invention provides a method for producing an electrode substrate for a photovoltaic cell, the method including disposing a photocatalytic compound on a transparent substrate, disposing a water-soluble polymeric compound on the photocatalytic layer to form a water-soluble polymer layer, exposing the photocatalytic layer and the water-soluble polymer layer to light and dipping the exposed substrate in an aqueous solution of metal ions to form a metal catalyst layer.

Another exemplary embodiment according to the present invention provides a method of manufacturing a dye-sensitized photovoltaic cell, the method including forming a semiconductor layer on a first electrode, forming a dye on a surface of the semiconductor layer, disposing a second electrode opposite to the first electrode, the second electrode and disposing an electrolyte between the first and second electrodes. The second electrode includes a transparent substrate, a photocatalytic layer formed on the transparent substrate and a metal catalyst layer formed on the photocatalytic layer.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view schematically showing the structure of an exemplary embodiment of a photovoltaic cell according to the present invention; and

FIG. 2 is a scanning electron micrograph (SEM) showing the surface of an exemplary embodiment of a second electrode produced in Preparative Example 1 of the present invention before exposure to ultraviolet (UV) light; and

FIG. 3 is a scanning electron micrograph (SEM) showing the surface of an exemplary embodiment of a second electrode produced in Preparative Example 1 of the present invention after exposure to UV light and Pt deposition.

### DESCRIPTION OF THE INVENTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

It will be understood that, although the terms first, second, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present invention will now be described in more detail with reference to the accompanying drawings.

An exemplary embodiment of the present invention provides a dye-sensitized photovoltaic cell including a first electrode, a semiconductor layer formed on the first electrode, a dye adsorbed on the surface of the semiconductor layer, a second electrode arranged opposite to the first electrode and consisting of a photocatalytic layer and a metal catalyst layer formed sequentially on a transparent substrate, and an electrolyte filled into a space formed between the first and second electrodes.

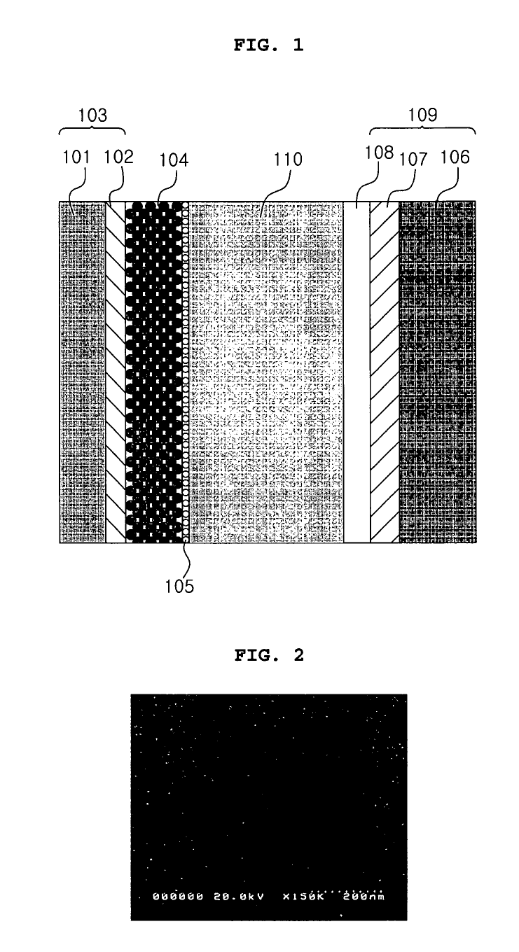

FIG. 1 is a cross-sectional view schematically showing the structure of an exemplary embodiment of a dye-sensitized photovoltaic cell according to the present invention. Referring to FIG. 1, the photovoltaic cell comprises a first electrode 103 consisting of a substrate 101 and a conductive material 102 coated on the substrate 101, a semiconductor layer 104 formed on the first electrode 103, a dye 105 adsorbed on the surface of the semiconductor layer 104. A second electrode 109 is arranged opposite to the first electrode 103 and consists of a photocatalytic layer 107 and a metal catalyst layer 108 formed sequentially on a transparent substrate 106 coated with a transparent conductive material 102′ (not shown), and an electrolyte 110 filled into a space formed between the first and second electrodes.

In other exemplary embodiment of dye-sensitized photovoltaic cells, a counter electrode (i.e. a second electrode) is produced by forming a metal catalyst layer, e.g., a platinum layer, on a transparent substrate. In contrast, an exemplary embodiment of a photovoltaic cell of the present invention, the second electrode 109 may be produced by forming a photocatalytic layer on a transparent substrate and then forming a metal catalyst layer on the photocatalytic layer so that the metal catalyst layer can be uniformly formed.

According to this structure of the exemplary embodiment of the second electrode 109, the processing efficiency and catalytic activity of the metal catalyst layer may advantageously be improved, which leads to an increase in the power conversion efficiency of the photovoltaic cell and is economically advantageous due to a reduction of production costs and processes.

The photocatalytic layer 107 may be formed using a photocatalytic compound. The “photocatalytic compound” may include a compound whose characteristics are drastically changed by light. The photocatalytic compound may be inactive when not exposed to light, but its reactivity may be activated upon exposure to light, e.g., UV light. When the photocatalytic compound is exposed to UV light, electron excitation occurs in an exposed portion, thus exhibiting an activity, e.g., reducibility. A reduction of metal ions, including, but not limited to, platinum (Pt) and palladium ions, in the exposed portion takes place to provide a metal catalyst layer.

Exemplary embodiment of photocatalytic compounds include Ti-containing organometallic compounds which can form transparent TiO₂ after annealing. Exemplary embodiments of the Ti-containing organometallic compounds include, but are not limited to, tetraisopropyl titanate, tetra-n-butyl titanate, tetrakis(2-ethyl-hexyl) titanate, polybutyl titanate and any compound suitable for the purpose described herein.

In an exemplary embodiment, the photocatalytic layer 107 may be formed to a thickness of about 10 nanometers (nm) to about 100 nanometers (nm) on the transparent substrate 106.

Exemplary embodiments of the transparent substrate 106 include, but are not limited to, glass and transparent plastic substrates. Exemplary embodiment of the transparent plastic substrates, include, but are not limited to, acrylic resins, polyesters, polycarbonates, polyethylenes, polyethersulfones, olefin-maleimide copolymers, norbornene-based resins, and the like. In other exemplary embodiments, polyethylene naphthalates and polyethylene terephthalates are preferably used for the transparent substrate 106.

Exemplary embodiments of the conductive material 102′ that may be coated on the substrate 106 include, but are not limited to, indium tin oxide (ITO) and fluorine-doped tin oxide (FTO).

Exemplary embodiments of metals as materials for the metal catalyst layer 108 of the photovoltaic cell include, but are not limited to, platinum, palladium, gold, and silver.

In exemplary embodiments, the substrate 101 constituting the first electrode 103 of the photovoltaic cell may be a metal foil or a transparent substrate. Exemplary embodiments of the metal foil include, but are not limited to, stainless steel, aluminum, transition metals, such as zinc, titanium, gold and silver, and alloys thereof. In other exemplary embodiments, the transparent substrate may be made of glass or transparent plastic, or the like.

In one exemplary embodiment where a highly heat-resistant metal foil is used as the substrate 101 of the first electrode, high-temperature processing at 400-500° C. may be advantageously applied to the formation of the metal oxide semiconductor layer on the first electrode 11. Advantageously, the characteristics of the metal oxide is improved, leading to improved power conversion efficiency of the photovoltaic cell.

In another exemplary embodiment, the substrate 101 of the first electrode may be produced by coating the metal foil or transparent substrate with a conductive material 102. In alternative exemplary embodiments, the metal foil may be directly used as the first electrode 101. The metal foil coated with the conductive material may be preferably used as the first electrode 101 because the contact resistance between the conductive material and the metal oxide semiconductor layer may be increased.

Exemplary embodiments of the conductive material 102 coated on the substrate may include, but are not limited to, indium tin oxide (ITO), fluorine-doped tin oxide (FTO), ZnO—Ga₂O₃, ZnO—Al₂O₃, and SnO₂—Sb₂O₃.

In other exemplary embodiments, the semiconductor layer 104 of the photovoltaic cell according to the present invention may be made of a porous metal oxide. The metal oxide used herein may include, but is not limited to, titanium oxide, niobium oxide, hafnium oxide, tungsten oxide, tin oxide, zinc oxide and any combination including at least one of the foregoing as suitable for the purpose described herein. In one exemplary embodiment, titanium oxide (TiO₂) may be preferably used.

In exemplary embodiments, the metal oxide constituting the semiconductor layer 104 may have a relatively large surface area such that the dye adsorbed on the surface of the metal oxide ultimately absorbs as much light as possible and the degree of adsorption to the electrolyte layer may be increased. In other exemplary embodiments, it is preferred that the semiconductor layer 104 have a nanostructure, such as nanotubes, nanowires, nanobelts or nanoparticles.

In another exemplary embodiment, the semiconductor layer 104 may be formed into a monolayer or a bilayer structure using two or more kinds of metal oxides having different particle sizes. In one exemplary embodiment, it is preferred that the bilayer structure consists of a layer ranging from about 5 micrometers (μm) to about 20 micrometers (μm) in thickness. In another exemplary embodiment, it is preferred that the semiconductor layer 104 be composed of a metal oxide having a particle size ranging from about 7 nm to about 20 nm and a layer composed of a metal oxide having a thickness from about 4 μm to about 10 μm and a particle size ranging from bout 200 nm to about 400 nm.

In exemplary embodiments, the formation of the semiconductor layer 104 may be performed by a coating technique. Coating techniques include, but are not limited to, spraying, spin coating, dipping, printing, doctor blading or sputtering. In other exemplary embodiments, the semiconductor layer 104 further undergoes drying and baking after coating. In one exemplary embodiment, the drying may be performed at about 50° C. to about 100° C., and the baking can be performed at about 400° C. to about 500° C.

An exemplary embodiment of the photovoltaic cell of the present invention includes a dye 105 adsorbed on the surface of the semiconductor layer 104. The dye 105 absorbs light and undergoes electronic transitions from a ground state to an excited state to form electron-hole pairs. The excited electrons are injected into a conduction band (CB) of the metal oxide semiconductor layer 104 and transferred to the electrodes to generate an electromotive force.

The dye 105 may include any of a number of materials so long as the dye is suitable for the purpose described herein, such as compounds generally used in the field of photovoltaic cells. In one exemplary embodiment, ruthenium complexes are preferred. In other exemplary embodiments, in addition to ruthenium complexes, any of a number of colorants may be used without particular limitation if its charge separation functions and sensitizing functions are not impaired. Exemplary embodiments of colorants include, but are not limited to, xanthene-type colorants, such as Rhodamine B, Rose Bengal, eosin and erythrosine; cyanine-type colorants, such as quinocyanine and cryptocyanine; basic dyes, such as phenosafranine, Capri blue, thiosine, and Methylene Blue; porphyrin-type compounds, such as chlorophyll, zinc porphyrin, and magnesium porphyrin; azo colorants; phthalocyanine compounds; complex compounds, such as Ru trisbipyridyl; anthraquinone-type colorants; polycyclic quinone-type colorants; and the like and any combination including at least one of the foregoing. Exemplary embodiments of the ruthenium complexes, may include RuL₂(SCN)₂, RuL₂(H₂O)₂, RuL₃, and RuL₂ (wherein L is 2,2′-bipyridyl-4,4′-dicarboxylate, etc.).

In another exemplary embodiment, the semiconductor layer 104 formed on one surface of the first electrode may be impregnated with a solution containing a photosensitive dye for 12 hours or more to adsorb the dye 105 on the semiconductor layer 104. Exemplary embodiments of solvents that can be used in the solution containing a photosensitive dye include, but are not limited to, tert-butyl alcohol, acetonitrile, and a mixture thereof.

In exemplary embodiment, the electrolyte 110 of the photovoltaic cell according to the present invention may include an electrolytic solution, for example, a solution of iodine in acetonitrile, an N-methyl-2-pyrrolidone (NMP) solution, or a 3-methoxypropionitrile solution. Any of a number of electrolytic solutions may be used without limitation so long as it exhibit hole conductive functions and is suitable for the purposes described herein.

The present invention also provides an exemplary embodiment of a method for producing an electrode substrate for the photovoltaic cell.

In one exemplary embodiment, the method of includes (i) coating a photocatalytic compound on a transparent substrate to form a photocatalytic layer; (ii) coating a water-soluble polymeric compound on the photocatalytic layer to form a water-soluble polymer layer; (iii) exposing the photocatalytic layer and the water-soluble polymer layer to light; and (iv) dipping the exposed substrate in an aqueous solution of metal ions to form a metal catalyst layer.

Hereinafter, the method of the present invention will be explained in detail, based on the respective steps.

Regarding Step (i),first, a photocatalytic compound is coated on a transparent substrate to form a photocatalytic layer. In one exemplary embodiment, the transparent substrate used herein is preferably a transparent plastic substrate coated with a conductive material, such as indium tin oxide-polyethylene terephthalate (ITO-PET) or indium tin oxide-polyethylene naphthalate (ITO-PEN). As explained earlier, the photocatalytic compound is inactive when not exposed to light, but its reactivity is activated upon exposure to light, e.g., UV light. When the photocatalytic compound is exposed to UV light, electron excitation occurs in the exposed portion, thus exhibiting activity, e.g., reducibility. Reduction of metal ions in the exposed portion takes place during the subsequent dipping treatment using an aqueous solution of metal ions such that the metal ions are substantially uniformly deposited on the surface of the exposed portion.

The photocatalytic compound is dissolved in an appropriate solvent, e.g., isopropyl alcohol, and then the solution is coated on the substrate by spin coating, spray coating, screen printing, or the like. After coating, the coating layer is heated on a hot plate or in a convection oven at a temperature of 120° C. or below for a predetermined period of time to form a photocatalytic layer. In exemplary embodiments, the predetermined period of time is not more than 20 minutes. Heating to a temperature exceeding 200° C. may lead to deformation of the plastic substrate, unfavorably resulting in poor optical properties. Regarding Step (ii), a water-soluble polymeric compound is coated on the photocatalytic layer to form a water-soluble polymer layer. The water-soluble polymeric compound may include a homopolymer, such as polyvinylalcohol, polyvinylphenol, polyvinylpyrrolidone, polyacrylic acid or polyacrylamide, gelatin, or a copolymer thereof.

A solution of 2 wt %-30 wt % of the water-soluble polymer in water is coated on the photocatalytic layer by a general coating process, followed by heating, to form a water-soluble polymer layer. In one exemplary embodiment, a water-soluble polymeric compound is coated by the same process as the coating process employed in the formation of the photocatalytic layer, and heated to 100° C. or below for not more than 5 minutes to evaporate water, completing the formation of a water-soluble polymer layer. In another exemplary embodiment, the thickness of the water-soluble polymer layer is ranges from about 0.1 μm to 1 μm.

The water-soluble polymer layer thus formed serves to promote photoreduction upon the subsequent exposure to UV light, thus acting to improve the photocatalytic activity. In an exemplary embodiment, a photosensitizer may be added to the aqueous water-soluble polymer layer to increase the photosensitivity of the water-soluble polymer layer. Exemplary embodiment of the photosensitizer include, but are not limited to, a water-soluble compound selected from colorants, organic acids, organic acid salts, and organic amines. Other exemplary embodiments of the photosensitizer include, but are not limited to, tar colorants, potassium and sodium salts of chlorophylline, riboflavin and derivatives thereof, water-soluble annatto, CUSO₄, caramel, curcumine, cochinal, citric acid, ammonium citrate, sodium citrate, oxalic acid, potassium tartarate, sodium tartarate, ascorbic acid, formic acid, triethanolamine, monoethanolamine, and malic acid. In one exemplary embodiment, the amount of the photosensitizer added is in the range of about 0.01 to about 5 parts by weight, based on 100 parts by weight of the water-soluble polymer. Regarding Step (iii), the composite structure consisting of the photocatalytic layer and the water-soluble polymer layer is exposed to light so that the metal catalyst layer is formed substantially uniformly during the subsequent dipping treatment. Any of a number of exposure conditions, including exposure atmospheres and doses, may be used as is suitable for the purposes described herein. By varying the exposure conditions and the subsequent dipping treatment conditions, the transmittance of the final second electrode may be changed and effectively controlled. In one exemplary embodiment, for sufficient transmittance and catalytic activity of the second electrode, the composite structure is preferably irradiated using a UV exposure system at about 200 to about 1,500 watts (W) for about 0.5 minute to about 5 minutes.

Regarding Step (iv) , the exposed substrate obtained in step (iii) is dipped in an aqueous solution of metal ions for a specific time to deposit metal particles on the surface of the exposed portion to form a metal catalyst layer. The water-soluble polymer and the photosensitizer are substantially or completely dissolved in the aqueous solution of metal ions, and are finally removed.

In exemplary embodiment, the aqueous solution of metal ions may be appropriately varied depending on the kind of metal of a metal catalyst layer to be formed. In one exemplary embodiment, the aqueous solution of metal ions is preferably a platinum salt or palladium salt solution. Compounds of the metal ions may be platinum and palladium halides and complexes. In another exemplary embodiment, taking into consideration the reactivity and price, metal chlorides, such as platinum chlorides and palladium chlorides, are preferably used.

In exemplary embodiments, for more efficient deposition of the metal particles, if needed, a pH-adjusting agent, e.g., hydrochloric acid, a buffering agent, e.g., KCl or NaCl, or the like may be further added to the aqueous solution of metal ions.

Deposition conditions of the metal ions may include any of a number and combination of conditions. The transmittance of the second electrode can be controlled by varying the deposition conditions. In one exemplary embodiment, for sufficient transmittance of the second electrode, it is preferred to deposit the metal ions at approximately room temperature for about 0.1 minute to about 20 minutes. In another exemplary embodiment according to the present invention, the visible light transmittance of the photovoltaic cell may be controlled within a range of about 20% to about 80%. In another exemplary embodiment according to the present invention, the transmittance of the photovoltaic cell may be preferably adjusted to 50% or above and taking the power conversion efficiency of general photovoltaic cells into consideration.

Hereinafter, exemplary embodiments of the present invention will be explained in more detail with reference to the following examples, including preparative examples. However, these examples are given for the purpose of illustration and are not to be construed as limiting the scope of the invention.

[Production of Second Electrodes]

### PREPARATIVE EXAMPLE 1

A solution of polybutyl titanate (5.0wt %) in isopropanol was applied to a transparent ITO-PEN substrate by spin coating at 2,000 revolutions per minute (rpm), and was then dried on a hot plate at 100° C. for 5 minutes to form a photocatalytic layer having a thickness of about 20 nm. A solution of 10 grams (g) of polyvinyl alcohol (molecular weight: ˜6,000), 12 g of citric acid, 1.0 milliliter (ml) of triethanolamine and 15 ml of isopropyl alcohol in 200 ml of distilled water was spin-coated at 2,000 rpm on the photocatalytic layer, and was then dried on a hot plate at 60° C. for 2 minutes to form a water-soluble polymer layer having a thickness of 400 nm. The resulting structure was irradiated with UV rays at 500 W using a UV exposure system (Oriel, U.S.) in a broad range of wavelengths.

After the exposure, the exposed substrate was dipped in a solution of 0.6 g of PtCl₂, 10 g of KCl and 10 ml of concentrated hydrochloric acid in one liter of distilled water for 5 minutes to deposit Pt particles on the surface of the exposed portion, completing the formation of a metal catalyst layer consisting of Pt particles. The water-soluble polymer layer was washed away when dipped in the aqueous solution after UV exposure.

### PREPARATIVE EXAMPLE 2

A second electrode was produced in the same manner as in Preparative Example 1, except that the UV exposure was conducted at 1,000 W for one minute and the dipping was conducted for one minute.

[Evaluation of Characteristics of Second Electrodes]

(1) Measurement of Transmittance

To measure changes in transmittance according to different UV exposure and Pt deposition conditions, the transmittance of the second electrodes produced in Preparative Examples 1 and 2 was measured using a UV-visible spectrophotometer. As a result of the measurement, the second electrode of Preparative Examples 1 had a transmittance of 50%, and the second electrode produced in Preparative Example 2 had a transmittance of 65%.

(2) Observation of Surface State

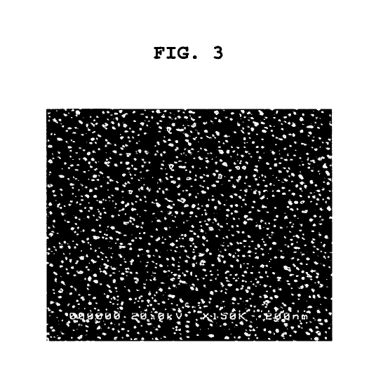

The surface state of the second electrode produced in Preparative Example 1 was observed under a scanning electron microscope (SEM). The obtained micrographs before UV exposure and after UV exposure and Pt deposition are shown in FIGS. 2 and 3, respectively. Referring to FIGS. 2 and 3, Pt particles are uniformly formed on the surface of the photocatalytic layer after exposure and Pt deposition when compared to before exposure.

[Fabrication of photovoltaic cells]

### EXAMPLE 1

ITO was deposited to a thickness of 100 nm on a stainless steel foil (thickness: 0.5 μm) to form a 100 nm-thick ITO film. Thereafter, a TiO₂ paste having an average particle size of 12 nm (Ti-nanoxide HTSP, Solaronix) was screen-printed on the ITO film, and baked at 500° C. for 30 minutes to form a 7 μm-thick semiconductor layer. Subsequently, the resulting structure was dipped in a 0.3 millimole (mM) ruthenium dithiocyanate 2,2′-bipyridyl-4,4′-dicarboxylate solution for 12 hours and dried to adsorb the dye on the surface of the TiO₂ layer, completing the production of a first electrode.

Separately, a solution of polybutyl titanate (5.0 wt %) in isopropanol was applied to a transparent ITO-PEN substrate by spin coating at 2,000 rpm, and was then dried on a hot plate at 100° C. for 5 minutes to form a photocatalytic layer having a thickness of about 20 nm. A solution of log of polyvinyl alcohol (molecular weight: ˜6,000), 12g of citric acid, 1.0 ml of triethanolamine and 15 ml of isopropyl alcohol in 200 ml of distilled water was spin-coated at 2,000 rpm on the photocatalytic layer, and was then dried on a hot plate at 60° C. for 2 minutes to form a water-soluble polymer layer having a thickness of 400 nm. The resulting structure was irradiated with UV rays at 500 W for one minute using a UV exposure system (Oriel, U.S.) in a broad range of wavelengths. After the exposure, the exposed substrate was dipped in a solution of 0.6 g of PtCl₂, log of KCl and 10 ml of conc. hydrochloric acid in one liter of distilled water for one minute to form a metal catalyst layer consisting of Pt particles, completing the production of a second electrode.

Subsequently, a polymer (SURLYN, DuPont) having a thickness of about 40 μm was interposed between the first electrode and the second electrode, and the two electrodes were adhered to each other under about 1 to about 3 atmospheres (atm) on a hot plate at about 100° C. to about 140° C. After a fine hole was formed so as to penetrate the second electrode, an electrolytic solution was filled into a space formed between the two electrodes through the fine hole to fabricate a photovoltaic cell of the present invention. At this time, as the electrolytic solution, an I₃⁻/I⁻ solution of 0.6 moles of 1,2-dimethyl-3-octyl-imidazolium iodide, 0.2 moles of LiI, 0.04 moles of I₂ and 0.2 moles of 4-tert-butyl-pyridine (TBP) in acetonitrile was used.

### EXAMPLE 2

A photovoltaic cell was fabricated in the same manner as in Example 1, except that the thickness of the TiO₂ layer constituting the semiconductor layer was changed to 5 μm.

### EXAMPLE 3

A photovoltaic cell was fabricated in the same manner as in Example 1, except that the thickness of the TiO₂ layer constituting the semiconductor layer was changed to 9 μm and the semiconductor layer was dipped in the 0.3 mM ruthenium dithiocyanate 2,2′-bipyridyl-4,4′-dicarboxylate solution for 24 hours to adsorb the dye on the surface of the semiconductor layer.

### EXAMPLE 4

A photovoltaic cell was fabricated in the same manner as in Example 3, except that a paste (Ti-nanoxide HTSP, Solaronix) having an average size of 12 nm was laminated to a thickness of 10 μm and a paste (Ti-nanoxide 300, Solaronix) having an average size of 300 nm was laminated to a thickness of 6.5 μm to form a bilayer TiO₂ layer.

[Evaluation of Characteristics of Photovoltaic Cells]

(1) Measurement of Transmittance

The transmittance of the photovoltaic cells fabricated in Examples 1 to 4 was measured in accordance with the procedure described above. The results are shown in Table 1.

(2) Evaluation of Power Conversion Efficiency

To evaluate the power conversion efficiency of the photovoltaic fabricated in Examples 1 to 4, the photovoltages and photocurrents of the cells were measured. For the measurements, a xenon lamp (Oriel, 01193) was used as a light source, and a standard photovoltaic cell (Frunhofer Institute Solar Engeriessysteme, Certificate No. C-ISE369, Type of material: Mono-Si+KG filter) was used to compensate for the simulated illumination conditions (AM 1.5) of the xenon lamp. The current density (I_{sc}), voltage (V_{oc}) and fill factor (FF) of the cells were calculated from the obtained photocurrent-photovoltage curves, and the power conversion efficiency (ηₑ) of the cells was calculated according to the following equation:
ηₑ=(V_{oc}·I_{sc}·FF)/(P_{inc})

where P_{inc} is 100 mw/cm² (1 sun).

The obtained results are shown in Table 1.

TABLE 1

| Example No. | Transmittance (%) | Power conversion efficiency (%) |
|---|---|---|
| Example 1 | 62 | 1.21 |
| Example 2 | 65 | 1.26 |
| Example 3 | 66 | 1.35 |
| Example 4 | 65 | 0.94 |

As observed from the results shown in Table 1, exemplary embodiment of the photovoltaic cells of the present invention advantageously have a sufficiently high transmittance and exhibit high power conversion efficiency.

In an exemplary embodiment according to the present invention, a photovoltaic cell includes a structure where a metal catalyst layer is formed on a photocatalytic layer. The metal catalyst layer can be formed substantially uniformly by light exposure and dipping treatments using the photocatalytic layer and a water-soluble polymer layer. Advantageously, the photovoltaic cell may be fabricated in a simplified manner at reduced costs. In addition, the photovoltaic cell advantageously exhibits high power conversion efficiency.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A dye-sensitized photovoltaic cell, comprising:
a first electrode;
a semiconductor layer formed on the first electrode;
a dye formed on a surface of the semiconductor layer;
a second electrode arranged opposite to the first electrode and comprising:
a transparent substrate,
a photocatalytic layer formed on the transparent substrate, and
a metal catalyst layer formed on the photocatalytic layer; and
an electrolyte disposed between the first and second electrodes.

2. The dye-sensitized photovoltaic cell according to claim 1, wherein the photocatalytic layer includes a photocatalytic compound.

3. The dye-sensitized photovoltaic cell according to claim 2, wherein the photocatalytic compound includes a compound that is electron-excitable when exposed to light to exhibit activity.

4. The dye-sensitized photovoltaic cell according to claim 3, wherein the light is ultraviolet (UV) light.

5. The dye-sensitized photovoltaic cell according to claim 3, wherein the photocatalytic compound includes a Ti-containing organometallic.

6. The dye-sensitized photovoltaic cell according to claim 5, wherein the photocatalytic compound is capable of forming TiO₂ after annealing.

7. The dye-sensitized photovoltaic cell according to claim 5, wherein the Ti-containing organometallic compound includes tetraisopropyl titanate, tetra-n-butyl titanate, tetrakis(2-ethyl-hexyl) titanate, polybutyl titanate or a combination including at least one of the foregoing.

8. The dye-sensitized photovoltaic cell according to claim 1, wherein a thickness of the photocatalytic layer is in a range of about 10 nm to about 100 nm.

9. The dye-sensitized photovoltaic cell according to claim 1, wherein the metal catalyst layer is one of platinum, palladium, gold, silver and a combination including at least one of the foregoing.

10. The dye-sensitized photovoltaic cell according to claim 1, wherein the first electrode comprises a metal foil or a transparent substrate.

11. The dye-sensitized photovoltaic cell according to claim 10, wherein the metal foil is one of stainless steel, transition metals, including aluminum, zinc, titanium, gold and silver, alloys thereof, and a combination including at least one of the foregoing.

12. The dye-sensitized photovoltaic cell according to claim 10, wherein the transparent substrate includes glass, transparent plastic or a combination including at least one of the foregoing.

13. The dye-sensitized photovoltaic cell according to claim 1, wherein the first electrode comprises a conductive material disposed on a substrate.

14. A method for producing an electrode substrate for a photovoltaic cell, comprising the steps of:
disposing a photocatalytic compound on a transparent substrate to form a photocatalytic layer;
disposing a water-soluble polymeric compound on the photocatalytic layer to form a water-soluble polymer layer;
exposing the photocatalytic layer and the water-soluble polymer layer to light; and
dipping the exposed substrate in an aqueous solution of metal ions to form a metal catalyst layer.

15. The method according to claim 14, wherein the water-soluble polymeric compound is one of polyvinylalcohol, polyvinylphenol, polyvinylpyrrolidone, polyacrylic acid, polyacrylamide, gelatin, copolymers thereof and a combination including at least one of the foregoing.

16. The method according to claim 14, wherein the disposing a water-soluble polymeric compound on the photocatalytic layer comprises adding a photosensitizer to the aqueous water-soluble polymer layer.

17. The method according to claim 16, wherein the photosensitizer is one of colorants, organic acids, organic acid salts, organic amines and a combination including at least one of the foregoing.

18. The method according to claim 14, wherein the exposing the photocatalytic layer and the water-soluble polymer layer to light comprises irradiating with UV rays at about 200 W to about 1,500 W for about 0.5 minute to about 5 minutes.

19. The method according to claim 14, wherein, the dipping the exposed substrate in an aqueous solution of metal ions is performed at approximately room temperature for about 0.1 minute to about 20 minutes.

20. A method of manufacturing a dye-sensitized photovoltaic cell, comprising:
forming a semiconductor layer on a first electrode;
forming a dye on a surface of the semiconductor layer;
disposing a second electrode opposite to the first electrode, the second electrode comprising:
a transparent substrate,
a photocatalytic layer formed on the transparent substrate, and
a metal catalyst layer formed on the photocatalytic layer; and
disposing an electrolyte between the first and second electrodes.
